(19) United States
(12) Patent Application Publication
(10) Pub. No.: US 2015/0325787 A1
(43) Pub. Date: Nov. 12, 2015

(54) METHOD OF FILLING AN OPENING AND METHOD OF MANUFACTURING A PHASE-CHANGE MEMORY DEVICE USING THE SAME

(71) Applicants: Jun-Ku AHN, Hwaseong-si (KR); Jeong-Hee PARK, Hwaseong-si (KR)

(72) Inventors: Jun-Ku AHN, Hwaseong-si (KR); Jeong-Hee PARK, Hwaseong-si (KR)

(21) Appl. No.: 14/599,848

(22) Filed: Jan. 19, 2015

(30) Foreign Application Priority Data
May 7, 2014 (KR) 10-2014-0054040

(51) Int. Cl. H01L 45/00

(52) U.S. Cl. CPC H01L 45/1608; H01L 45/06; H01L 45/141; H01L 45/1666; H01L 45/1253; H01L 45/1233

(57) ABSTRACT

Example methods of filling an opening and of manufacturing a phase change memory device are disclosed. In an example method, an insulation layer having an opening is formed on a substrate. A material layer is formed on the insulation layer. The material layer fills the opening, and has a void. A first laser beam is irradiated onto the material layer, thereby removing the void or reducing a size of the void. The first laser beam is generated from a solid state laser medium.

### CROSS-REFERENCE TO RELATED APPLICATIONS

This application claims priority under 35 U.S.C §119 from Korean Patent Application No. 10-2014-0054040 filed on May 7, 2014 in the Korean Intellectual Property Office, the disclosure of which is incorporated by reference herein in its entirety.

### BACKGROUND

1. Field

Example embodiments relate to a method of filling an opening and/or a method of manufacturing a phase-change memory device using the same.

2. Description of the Related Art

A phase change memory device is typically a device for storing data using a resistance change generated by a phase transition between an amorphous state and a crystalline state of a phase change material layer pattern. For example, a transistor formed on a substrate may provide the phase-change material layer pattern with a reset current for changing the phase of the phase-change material layer pattern from the crystalline state into the amorphous state. The transistor may also supply the phase-change material layer with a set current for changing the phase of the phase-change material layer pattern from the amorphous state into the crystalline state.

During the processes for manufacturing the phase change memory device, the phase-change material layer pattern may fill an opening in an insulating interlayer. In this case, the material for forming the phase-change material layer pattern may have poor gap-fill characteristics and poor step coverage, so that it is typically difficult to fill the opening.

### SUMMARY

Example embodiments of the present inventive concepts relate to a method of filling an opening with an improved reliability.

Example embodiments of the present inventive concepts provide a method of manufacturing a phase-change memory device with an improved reliability.

At least one example embodiment of the present inventive concepts, relates to a method of filling an opening. In the example method, an insulation layer having an opening is formed on a substrate. A material layer is formed on the insulation layer. The material layer fills the opening, and has a void. A first laser beam is irradiated onto the material layer, thereby removing the void or reducing a size of the void. The first laser beam is generated from a solid state laser medium.

In an example embodiment, the material layer may include a chalcogenide compound.

In an example embodiment, the first laser beam may be an yttrium-aluminum-garnet (YAG) laser beam.

In an example embodiment, the first laser beam may have a wavelength in a range of about 500 nm to about 600 nm, or in a range of about 1000 nm to about 1200 nm.

In an example embodiment, an irradiation time of the first laser beam may be in a range of about 300 ns to about 1200 ns.

In an example embodiment, an energy density of the first laser beam may be in a range of about 440 mJ/cm² to about 1000 mJ/cm².

In an example embodiment, an energy density of the first laser beam may be in a range of about 440 mJ/cm² to about 500 mJ/cm².

In an example embodiment, the first laser beam may be irradiated under an inert gas atmosphere or a reactive gas atmosphere.

In an example embodiment, irradiating the first laser beam may include moving the void above a desired, or alternatively predetermined height.

In an example embodiment, the method may further comprise removing an upper portion of the material layer which surrounds the void, after irradiating the first laser beam.

In an example embodiment, irradiating the first laser beam may include reducing a surface roughness of a top surface of the material layer.

In an example embodiment, the method may further comprise irradiating a second laser beam onto the material layer, before irradiating the first laser beam.

In an example embodiment, irradiating the second laser beam may include forming a capping laser by oxidizing an upper portion of the material layer. An energy density of the second laser beam may be lower than an energy density of the first laser beam.

In an example embodiment, irradiating the first laser beam may include making compositions of an upper portion and a lower portion of the material layer uniform.

At least one example embodiment of the inventive concepts relate to a method of manufacturing a phase change memory device. In the example method, a switching structure is formed on a substrate. A lower electrode is formed to be electrically connected to the switching structure. An insulation layer is formed to have an opening. The opening exposes the lower electrode. A phase change material layer is formed on the insulation layer. The phase change material layer fills the opening, and has a void. A first laser beam is irradiated onto the phase change material layer, thereby removing the void or reducing a size of the void. The first laser beam is generated from a solid state laser medium. An upper portion of the phase change material layer is planarized to form a phase change material layer pattern filling the opening. An upper electrode is formed on the phase change material layer pattern.

According to example embodiments, a first laser beam generated from a solid state laser medium may be irradiated onto a material layer, so that a void may be effectively substantially removed, or may be reduced. Therefore, a material layer pattern may sufficiently fill an opening having a relatively large aspect ratio.

At least one example embodiment relates to a method of forming a phase-change memory structure including forming an insulation layer including an opening, forming a phase change material layer on the insulation layer to fill the opening, the phase change material having at least one void, and irradiating a laser beam onto the phase change material layer to one of remove and reduce the at least one void, wherein the phase change material remains substantially free of damage.

### BRIEF DESCRIPTION OF THE DRAWINGS

These and other features of the inventive concepts will become more apparent by describing in detail example embodiments thereof with reference to the accompanying drawings of which:

FIGS. 1 to 4 are cross-sectional views illustrating a method of manufacturing a phase change memory device in accordance with some example embodiments of the present inventive concepts;

FIGS. 5 to 8 are cross-sectional views illustrating a method of manufacturing a phase change memory device in accordance with other example embodiments of the present inventive concepts;

FIGS. 9 to 10 are cross-sectional views illustrating a method of manufacturing a phase change memory device in accordance with other example embodiments of the present inventive concepts;

FIGS. 11 to 13 are cross-sectional views illustrating a method of manufacturing a phase change memory device in accordance with other example embodiments of the present inventive concepts;

FIGS. 14 to 15 are cross-sectional views illustrating a method of manufacturing a phase change memory device in accordance with other example embodiments of the present inventive concepts;

FIGS. 16 to 29 are plan views and cross-sectional views illustrating a method of manufacturing a phase change memory device in accordance with other example embodiments of the present inventive concepts;

FIG. 30 is a graph illustrating a size of a void in a phase change material layer depending on an energy density of a laser beam;

FIG. 31 is a diagram schematically illustrating a memory system according to example embodiments of inventive concepts; and

FIG. 32 is a diagram illustrating a system according to example embodiments of inventive concepts.

### DETAILED DESCRIPTION OF THE EMBODIMENTS

Various example embodiments will be described more fully hereinafter with reference to the accompanying drawings, in which some example embodiments are shown. The example inventive concepts may, however, be embodied in many different forms and should not be construed as limited to the example embodiments set forth herein. Rather, these example embodiments are provided so that this disclosure will be thorough and complete, and will fully convey the scope of the example inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Hereinafter, example embodiments will be explained in detail with reference to the accompanying drawings. In the drawing figures, the dimensions of layers and regions may be exaggerated for clarity of illustration Like reference numerals refer to like elements throughout. The same reference numbers indicate the same components throughout the specification.

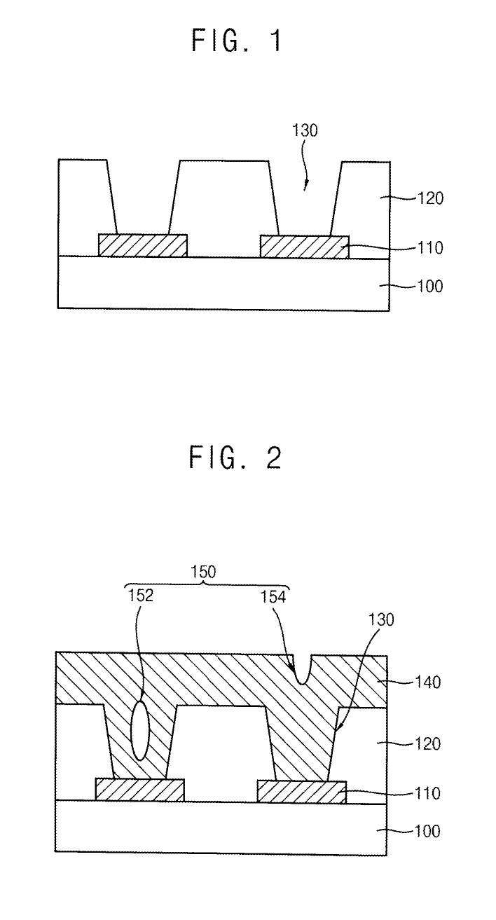

FIGS. 1 to 4 are cross-sectional views illustrating a method of manufacturing a phase change memory device in accordance with some example embodiments of the present inventive concepts.

Referring to FIG. 1, a lower electrode 110 is formed on a substrate 100, and an insulation layer 120 having an opening 130 is formed on the substrate 100.

Particularly, a first conductive layer may be formed on the substrate 100, and the first conductive layer may be partially removed to form the lower electrode 110. Then, the insulation layer 120 may be formed on the substrate 100 to cover at least a portion of the lower electrode 110, and the insulation layer 120 may be partially removed to form the opening 130 exposing a top surface of the lower electrode 110.

The substrate 100 may include a semiconductor substrate. Particularly, the substrate 100 may include a silicon substrate, a germanium substrate, a silicon-germanium substrate, a silicon-on-insulator (SOI) substrate, a germanium-on-insulator substrate, etc.

The lower electrode 110 may be formed by any one of a sputtering process, an atomic layer deposition (ALD) process, a chemical vapor deposition (CVD) process, and the like, using a metal, a conductive metal nitride, a conductive metal oxy nitride or a conductive silicon nitride. For example, the lower electrode 110 may be formed using aluminum, copper, tungsten, titanium nitride, tantalum nitride, molybdenum nitride, niobium nitride, titanium silicon nitride, titanium aluminum nitride, titanium boron nitride, zirconium silicon nitride, tungsten, tungsten nitride, conductive carbon, carbon nitride, tungsten silicon nitride, tungsten boron nitride, zirconium aluminum nitride, molybdenum silicon nitride, molybdenum aluminum nitride, tantalum silicon nitride, tantalum aluminum nitride, titanium oxy-nitride, titanium aluminum oxy-nitride, tungsten oxy-nitride, tantalum oxy-nitride, and the like.

The insulation layer 120 may be formed using an insulation material, such as an oxide or a nitride. For example, the insulation layer 120 may be formed using silicon oxide (SiOx), silicon nitride (SiNx), silicon oxy-nitride (SiOxNy), silicon carbon nitride (SiCxNy), titanium oxide (TiOx), zirconium oxide (ZrOx), magnesium oxide (MgOx), hafnium oxide (HfOx), aluminum oxide (AlOx), or a mixture thereof.

The insulation layer 120 may have a three dimensional shape including a recessed portion. In example embodiments, the insulation layer 120 may have the opening 130. Alternatively, the insulation layer 120 may have a hole, a trench, a recess, a gap or a contact pore.

In example embodiments, a sidewall of the opening 130 may be inclined as illustrated in FIG. 1, or may be perpendicular to the surface of the substrate 100. That is, a width of the opening 130 may gradually vary, or decrease, from a top portion of the opening 130 to a bottom portion of the opening 130.

The opening 130 may be formed through the insulation layer 120 to expose a top surface of the lower electrode 110 as illustrated in FIG. 1. In example embodiments, the opening 130 may at least partially expose the top surface of the lower electrode 110. That is, an area of the top surface of the lower electrode 110 exposed by the opening 130 may be less than a total area of the top surface of the lower electrode 110. Alternatively, the opening 130 may sufficiently expose the top surface of the lower electrode 110.

Referring to FIG. 2, a material layer 140 having at least a void 150 may be formed on the insulation layer 120 to partially fill the opening 130.

In example embodiments, the material layer 140 may be or include a phase change material layer including a chalcogenide compound. The phase change material layer may include at least one of tellurium (Te), selenium (Se), germanium (Ge), stibium (Sb), bismuth (Bi), lead (Pb), tin (Sn), arsenic (As), indium (In), sulfur (S), oxygen (O), palladium (Pd), platinum (Pt) and gold (Au). For example, the phase-change material layer may include at least one of Ge—Te, Ge—Sb—Te, Ge—Te—Se, Ge—Te—As, Ge—Te—Sn, Ge—Te—Ti, Ge—Bi—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, In—Sb—Te, Sb—Se and Ag—In—Sb—Te. The phase-change material layer may be doped with at least one of carbon (C), nitrogen (N), silicon (Si), oxygen (O), bismuth (Bi), and tin (Sn). For example, the phase change material layer may include Ge—Sb—Te doped with carbon or nitrogen. Therefore, the material layer 140 may include a material, which may have a melting temperature between about 550° C. and about 700° C.

In example embodiments, the material layer 140 may be formed by a physical vapor deposition (PVD) process, a CVD process, a low pressure CVD (LPCVD) process, a plasma enhanced CVD (PECVD) process, a high density plasma-CVD (HDP-CVD) process, an ALD process, etc. For example, the material layer 140 may be formed by a sputtering process, so that a process time for forming the material layer 140 may decrease.

As an aspect ratio of the opening 130 increases, and a width of the opening 130 decreases, the material layer 140 may partially fill the opening 130. That is, the void 150 may inevitably occur in the material layer 140.

The void 150 may include a first void 152 and/or a second void 154. The first void 152 may be entirely surrounded by the material layer 140, while the second void 154 may be at least partially surrounded by the materially layer 140, and may be partially exposed to an outer space environment. In example embodiments, the first void 152 may be located in the opening 130, and the second void 154 may be located at an upper portion of the material layer 140.

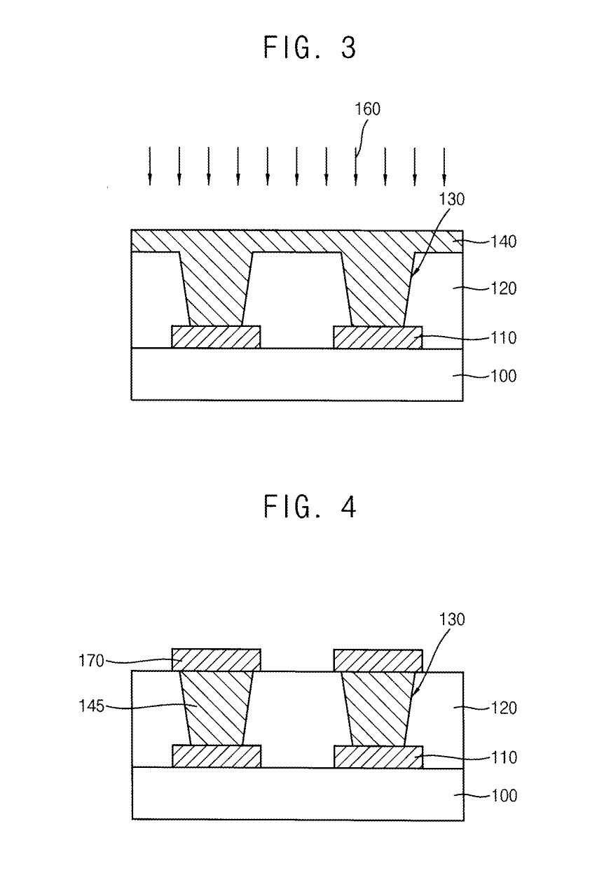

Referring to FIG. 3, a first laser beam 160 may be irradiated onto the material layer 140, and the material layer 140 may be heated to a temperature above a melting temperature thereof, so that the void 150 may be removed.

The first laser beam 160 may have enough energy to heat and melt the material layer 140. The first laser beam 160 may be a solid-state laser beam which may be generated from a solid state layer medium. In an example embodiment, the first laser beam 160 may be an yttrium-aluminum-garnet (YAG) laser beam. Further, in order to adjust a wavelength of the first laser beam 160, neodymium (Nd) or ytterbium (Yb) may be doped into a YAG laser medium. That is, the first laser beam 160 may be an Nd or Yb doped YAG laser beam.

The first laser beam 160 may have the wavelength which may vary depending on a doped concentration of Nd or Yb. The first laser beam 160 may have a wavelength in a range of about 500 nm to about 1200 nm. Particularly, the first laser beam 160 may have the wavelength in a range of about 500 nm to about 600 nm. Further, the wavelength of the first laser beam 160 may be doubled by an optical treatment, so that the first laser beam 160 may have a wavelength in a range of about 1000 nm to about 1200 nm. In an example embodiment, the first laser beam 160 may have a wavelength of about 515 nm. If the wavelength of the first laser beam 160 is less than about 500 nm, energy of the first laser beam 160 is too strong, so that the material layer 140 may be damaged. On the other hand, if the wavelength of the first laser beam 160 is greater than about 1200 nm, energy of the first laser beam 160 is too weak, so that the material layer 140 may not be melt within a desired, or alternatively predetermined period.

An energy density of the first laser beam 160 may be adjusted within a range of about 400 mJ/cm² to about 1000 mJ/cm². The energy density of the first laser beam 160 may vary depending on a composition of the material layer 140 and an irradiation time of the first laser beam 160. When the energy density of the first laser beam 160 is in a range of about 440 mJ/cm² to about 500 mJ/cm², the void 150 in the material layer 140 may be sufficiently removed (See FIG. 30). A relation between a size of the void 150 in the phase change material layer and the energy density of the first laser beam 160 may be described below with reference to FIG. 30.

The irradiation time of the first laser beam 160 may be in a range of about 300 ns to about 1200 ns. If the irradiation time of the first laser beam 160 is less than about 300 ns, the first laser beam 160 may not melt the material layer 140, and the void 150 may not be removed. On the other hand, if the irradiation time of the first laser beam 160 is greater than about 1200 ns, the material layer 140 may be partially vaporized, or a roughness of a top surface of the material layer 140 may be degraded by an ablation phenomena. That is, the void 150 may be effectively substantially removed, and a damage of the material layer 140 may be reduced or prevented, when the first laser beam 160 is irradiated onto the material layer for a desired, or alternatively predetermined period.

Further, an atmosphere of a process for irradiating the first laser beam 160 may be adjusted. For example, the process for irradiating the first laser beam 160 may be performed at an atmospheric pressure to a vacuum condition (<10⁻⁸ torr).

In example embodiments, the process for irradiating the first laser beam 160 may be performed under an inert gas atmosphere including a helium (He) gas, an neon (Ne) gas, an argon (Ar) gas or a krypton (Kr) gas. Alternatively, the process for irradiating the first laser beam 160 may be performed under an atmosphere including a hydrogen (H₂) gas, a nitrogen (N₂) gas or an oxygen (O₂) gas. For example, the process for irradiating the first laser beam 160 may be performed under an ambient atmosphere including the nitrogen (N₂) gas and the oxygen (O₂) gas.

Additionally, a temperature of the process for irradiating the first laser beam 160 may be less than about 500° C. That is, the process temperature may be less than the melting temperature of the material layer 140.

In other example embodiments, a beam size and a pulse waveform of the first laser beam 160 may be adjusted, so that the first laser beam 160 may be irradiated onto a desired, or alternatively predetermined portion of the material layer 140. Further, the number of irradiations of the first laser beam 160 may increase, while an energy density of the first laser beam 160 may decrease.

As the first laser beam 160 irradiates the material layer 140, the material layer 140 may be heated to the temperature above its own melting temperature (that is, about 550° C. to about 700° C.) of the material layer 140, and the void 150 may be removed. After the process for irradiating the first laser beam 160, the material layer 140 may be quenched. That is, the material layer 140 may undergo a melting step and a quenching step, the second void 154 at the upper portion of the material layer 140 as well as the first void 152 in the material layer 140 may be substantially reduced or removed, or effectively removed.

Referring to FIG. 4, at least an upper portion of the material layer 140 may be substantially removed to form a material layer pattern 145 filling the opening 130, and an upper electrode 170 may be formed on the material layer pattern 145.

Particularly, the material layer 140 may be planarized until a top surface of the insulation layer 120 is exposed, so that a top surface of the material layer pattern 145 may have an identical height to the top surface of the insulation layer 120. Then, a second conductive layer may be formed on the insulation layer 120 and the material layer pattern 145, and the second conductive layer may be partially removed to form the upper electrode 170.

In example embodiments, the upper electrode 170 may be formed using a metal, a conductive metal nitride, or a conductive silicon nitride.

According to example embodiments, the first laser beam 160 generated from the solid state laser medium may be irradiated onto the material layer 140, so that the first void 152 and the second void 154 may be substantially reduced or removed, or effectively removed. Therefore, the material layer pattern 145 may sufficiently fill the opening 130 having a relatively large aspect ratio.

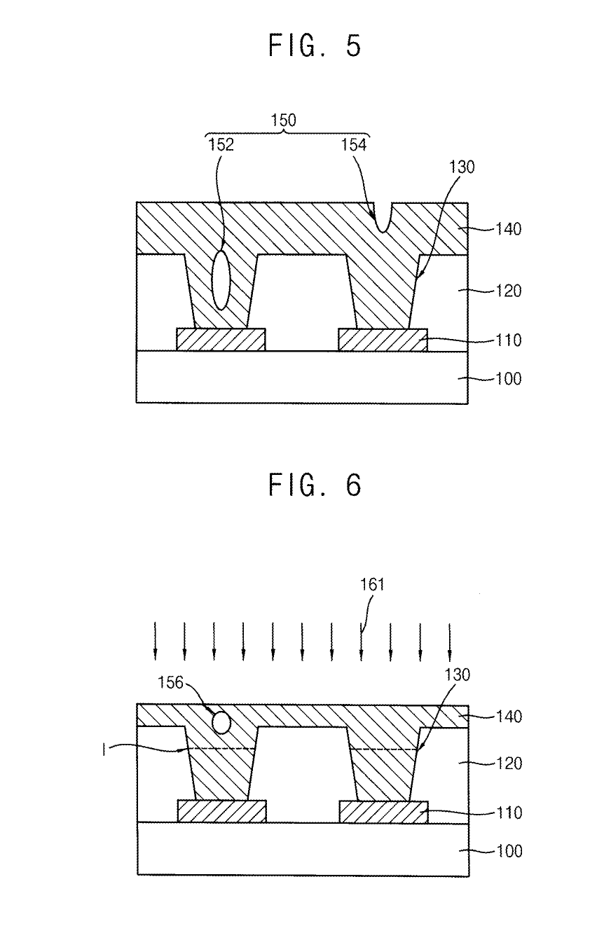

FIGS. 5 to 8 are cross-sectional views illustrating a method of manufacturing a phase change memory device in accordance with other example embodiments of the present inventive concepts. The method of manufacturing the phase change memory device of FIGS. 5 to 8 may be substantially identical to, substantially similar to or the same as the method described with reference to FIGS. 1 to 4 except for a remaining void 156 and an upper electrode 172.

Referring to FIG. 5, processes which may be substantially similar to or the same as those described with reference to FIGS. 1 and 2 may be performed. That is, a lower electrode 110 may be formed on a substrate 100, and an insulation layer 120 having an opening 130 may be formed. A material layer 140 having a first void 152 and a second void 154 may be formed to partially fill the opening 130.

Referring to FIG. 6, a first laser beam 160 may be irradiated onto the material layer 140, and the material layer 140 may be heated to a temperature above a melting temperature thereof, so that the second void 154 may be substantially removed, and a size of the first void 152 may be reduced.

The process for irradiating the first laser beam 160 may be substantially similar to or the same as the process described with reference to FIG. 3. However, an energy density of the first laser beam 160 of FIG. 6 may be less than the energy density of the first laser beam 160 of FIG. 3.

As the first laser beam 160 irradiates the material layer 140, the material layer 140 may be heated to a temperature above the melting temperature (that is, about 550° C. to about 700° C.) of the material layer 140, and the second void 154 disposed at an upper portion of the material layer 140, may be removed. Further, as the first laser beam 160 irradiates, a size of the first void 152 may decrease without being substantially or completely removed. Due to a capillary force of the molten material layer 140 and a gravity force, the size and the position of the first void 152 may change. That is, the first void 152 may be converted to the remaining void 156.

The size of the remaining void 156 may be less than the size of the first void 152. In example embodiments, the material surrounding the first void 152 may flow downward during the process for irradiating the first laser beam 160 because of gravity, and the remaining void 156 may move upward as a result. Accordingly, the remaining void 156 may be disposed above a desired, or alternatively predetermined height (I). That is, a bottom surface of the remaining void 156 (that is, a lowest interface between the remaining void 156 and the material layer 140) in a direction substantially perpendicular to the surface of the substrate 100 may be higher than the desired, or alternatively predetermined height (I). Further, the desired, or alternatively predetermined height (I) may be equal to a top surface of the insulation layer 120, or may be lower than the top surface of the insulation layer 120.

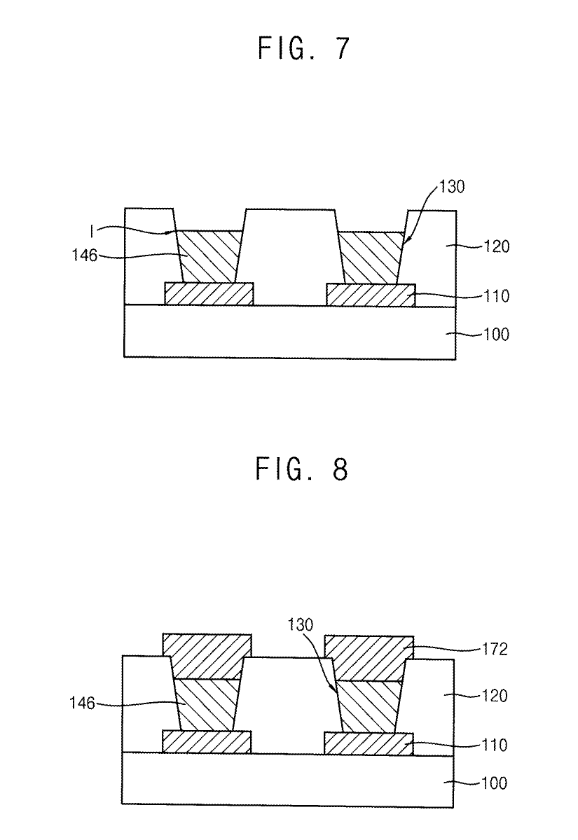

Referring to FIG. 7, an upper portion of the material layer 140 of FIG. 6 may be removed to form a material layer pattern 146 filling a lower portion of the opening 130.

Particularly, the material layer 140 of FIG. 6 may be planarized to the desired, or alternatively predetermined height (I) by a chemical mechanical planarization (CMP) and/or an etch back process, thereby forming the material layer pattern 146. Therefore, the material layer pattern 146 may fill the lower portion of the opening 130, and a top surface of the material layer pattern 146 may be equal to the top surface of the insulation layer 120, or may be lower than the top surface of the insulation layer 120.

As planarization process is performed, the upper portion of the material layer 140 of FIG. 6 above the desired, or alternatively predetermined height (I) may be removed. Therefore, the remaining void 156 (See, FIG. 6) disposed in the upper portion of the material layer 140 may be removed at the same time.

Referring to FIG. 8, an upper electrode 172 may be formed on the material layer pattern 146 to fill an upper portion of the opening 130.

Particularly, a second conductive layer may be formed on the insulation layer 120 and the material layer pattern 146 to fill the upper portion of the opening 130, and the second conductive layer may be at least partially removed to form the upper electrode 172. In example embodiments, the upper electrode 172 may have a substantially or approximate ‘T’ shape.

According to example embodiments, the first laser beam 160 generated from the solid state laser medium may be irradiated onto the material layer 140, so that the size and the position of the void 150 may be adjusted. Therefore, the material layer pattern 146 may sufficiently fill the opening 130 having a relatively large aspect ratio.

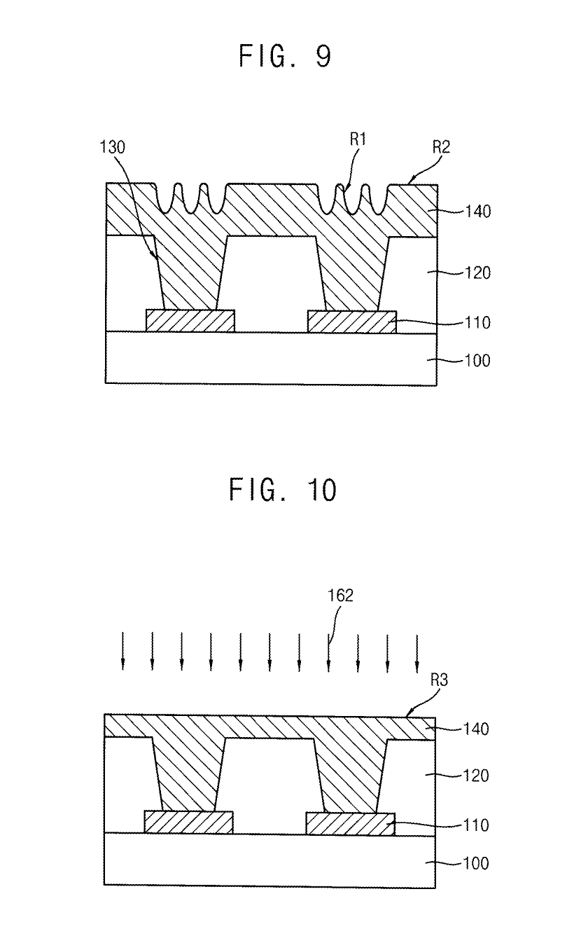

FIGS. 9 and 10 are cross-sectional views illustrating a method of manufacturing a phase change memory device in accordance with other example embodiments of the present inventive concepts. The method of manufacturing the phase change memory device of FIGS. 9 and 10 may be substantially identical to or substantially similar to or the same as those described with reference to FIGS. 1 to 4 except for a roughness of the material layer 140.

Referring to FIG. 9, processes which may be substantially similar to or the same as those described with reference to FIGS. 1 and 2 may be performed. That is, a lower electrode 110 may be formed on a substrate 100, and an insulation layer 120 having an opening 130 may be formed. A material layer 140 may be formed to partially fill the opening 130.

The material layer 140 may have a different surface roughness at different portion of the surface. In example embodiments, a top surface of the material layer 140 may have a first surface roughness (R1) in a first portion where the material layer 140 and the opening 130 overlap, while a top surface of the material layer 140 may have a second surface roughness (R2) in a second portion where the material layer 140 and the opening 130 do not overlap. For example, the first surface roughness (R1) may be greater than the second surface roughness (R2). If the surface roughness is greater than a desired, or alternatively predetermined value, a process variation may be degraded during a process for planarizing an upper portion of the material layer 140.

Referring to FIG. 10, a first laser beam 162 may be irradiated onto the material layer 140, and an upper portion of the material layer 140 may be heated to a temperature above a melting temperature thereof, so that a surface roughness of the material layer 140 may be reduced.

The process for irradiating the first laser beam 162 may be substantially similar to or the same as the process described with reference to FIG. 3. However, an energy density and an irradiation time of the first laser beam 162 of FIG. 10 may be less than the energy density and irradiation time of FIG. 3.

As the first laser beam 162 irradiates, the upper portion of the material layer 140 may be melt to flow. Therefore, the top surface of the material layer 140 may have a third surface roughness (R3) which is uniform in the first region and the second region. In this case, the third surface roughness (R3) may be less than the first surface roughness (R1).

According to example embodiments, the first laser beam 162 generated from the solid state laser medium may be irradiated onto the material layer 140, so that the surface roughness of the material layer 140 may be adjusted.

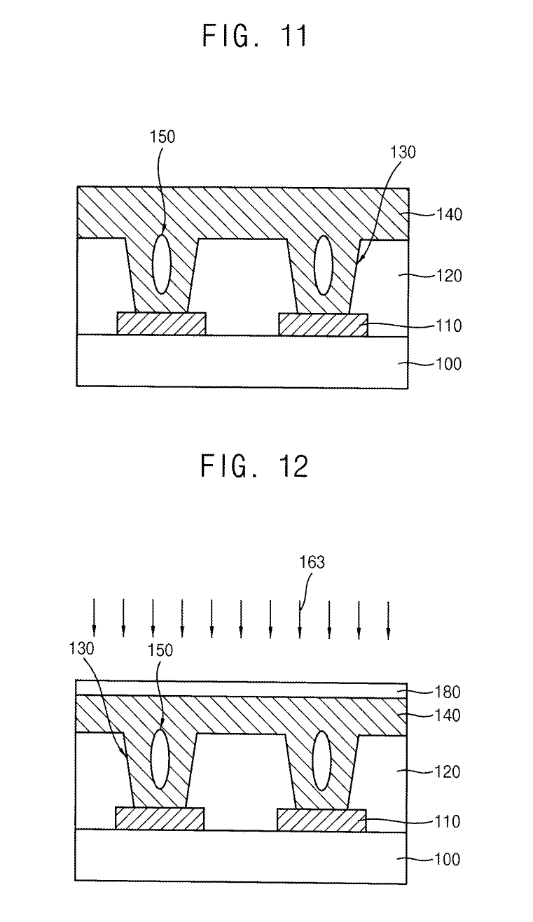

FIGS. 11 to 13 are cross-sectional views illustrating a method of manufacturing a phase change memory device in accordance with other example embodiments of the present inventive concepts. The method of manufacturing the phase change memory device of FIGS. 11 to 13 may be substantially identical to or substantially similar to or the same as the method described with reference to FIGS. 1 to 4 except for a capping layer 180.

Referring to FIG. 11, processes which may be substantially similar to or the same as those described with reference to FIGS. 1 and 2 may be performed. That is, a lower electrode 110 may be formed on a substrate 100, and an insulation layer 120 having an opening 130 may be formed. A material layer 140 including a void 150 may be formed to partially fill the opening 130.

Referring to FIG. 12, a second laser beam 163 may be irradiated onto the material layer 140, so that an upper portion of the material layer 140 may be converted to the capping layer 180.

The upper portion of the material layer 140 may be heated above a desired, or alternatively predetermined temperature by irradiating the second laser beam 163. In example embodiments, the second laser beam 163 may be an Nd or Yb doped YAG laser beam.

In example embodiments, the process for irradiating the second laser beam 163 may be performed under a reactive gas atmosphere including a nitrogen (N₂) gas or an oxygen (O₂) gas. The reactive gas may react with the upper portion of the material layer 140. For example, if the process for irradiating the second laser beam 163 may be performed under the oxygen gas atmosphere, the upper portion of the material layer 140 may be oxidized to form the capping layer 180. Alternatively, if the process for irradiating the second laser beam 163 may be performed under the nitrogen gas atmosphere, the upper portion of the material layer 140 may be nitrized to form the capping layer 180. That is, the second laser beam 163 may catalyze the reaction between the reactive gas and the material layer 140.

An energy density of the second laser beam 163 may be less than the energy density of the first laser beam 164, as described below. That is, as the second laser beam 163 irradiates, the material layer 140 may be heated to a temperature that is below the melting temperature (that is, about 550° C. to about 700° C.) of the material layer 140. Therefore, a void 150 in the material layer 140 may not be substantially removed.

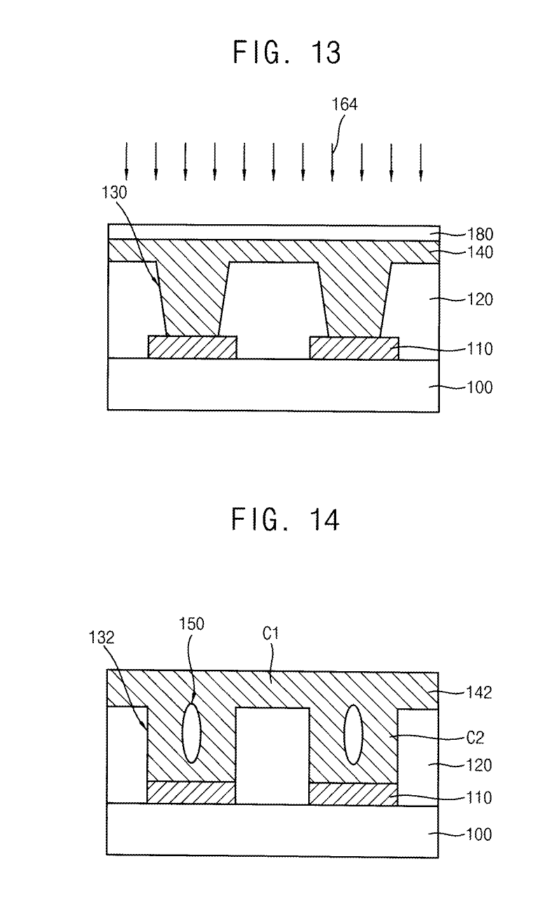

Referring to FIG. 13, a first laser beam 164 may be irradiated onto the material layer 140, and the material layer 140 may be heated to a temperature above a melting temperature thereof, so that the void 150 may be substantially removed.

The process for irradiating the first laser beam 164 may be substantially similar to or the same as those described with reference to FIG. 3.

However, the capping layer 180 may at least substantially cover the material layer 140 during the process of irradiating the first laser beam 164. The capping layer 180 may have a melting temperature which may be higher than the melting temperature of the material layer 140. Therefore, the capping layer 180 may not be melted during the process of irradiating the first laser beam 164. The capping layer 180 may reduce or prevent a vaporization or an ablation of the material layer 140. Further, the capping layer 180 may effectively transfer a heating energy of the first laser beam 164 to the material layer 140.

As the first laser beam 164 irradiates, the material layer 140 may be heated to the temperature above the melting temperature (that is, about 550° C. to about 700° C.) of the material layer 140, and the void 150 in the material layer 140 may be removed.

According to example embodiments, the first laser beam 164 and the second laser beam 163 generated from the solid state laser medium may be irradiated onto the material layer 140, so that the void 150 may be effectively removed. The capping layer 180 may reduce or prevent a damage of the material layer 140 during the process for irradiating the first laser beam 164.

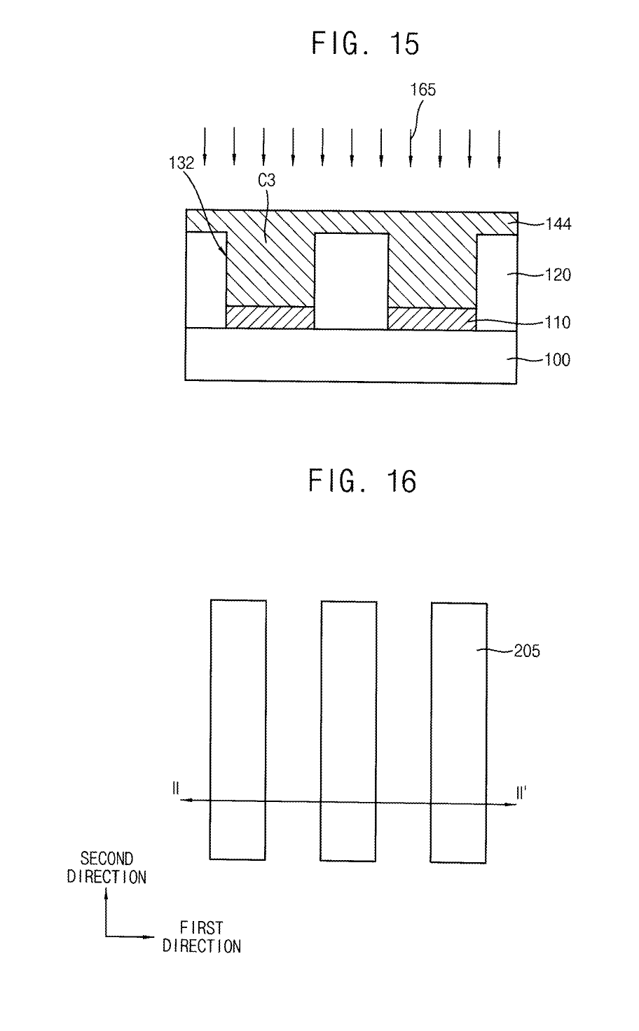

FIGS. 14 and 15 are cross-sectional views illustrating a method of manufacturing a phase change memory device in accordance with other example embodiments of the present inventive concepts.

Referring to FIG. 14, processes which may be substantially similar to or the same as the processes described with reference to FIGS. 1 and 2 may be performed. That is, a lower electrode 110 may be formed on a substrate 100, and an insulation layer 120 having an opening 132 may be formed. A material layer 140 having a first void 152 and a second void 154 may be formed to at least partially fill the opening 130.

However, the opening 132 may fully or substantially expose a top surface of the lower electrode 110. Further, a sidewall of the opening 132 may be substantially perpendicular to a top surface of the substrate 100.

In example embodiments, the material layer 140 may be formed by a PVD process, such as a sputtering process. Due to a three dimensional shape of the opening 132, the composition of the material layer 140 may not be uniform.

For example, when the material layer 140 includes Ge—Sb—Te, a lower portion of the material layer 140 in the opening 132 may have a first composition (C1), while an upper portion of the material layer 140 may have a second composition (C2). In this case, the first composition (C1) may have higher Ge atomic % than the second composition (C2).

Referring to FIG. 15, a first laser beam 165 may be irradiated onto the material layer 140, and the material layer 140 may be heated to a temperature above a melting temperature thereof, so that the compositions of the upper portion and the lower portion of the material layer 140 may be substantially uniform.

The process for irradiating the first laser beam 165 may be substantially similar to or the same as the process described with reference to FIG. 3. As the first laser beam 160 irradiates the material layer 140, the material layer 140 may be heated to the temperature above the melting temperature (that is, about 550° C. to about 700° C.) of the material layer 140, the material layer 140 may have a substantially uniform composition due to a diffusion of Ge atoms.

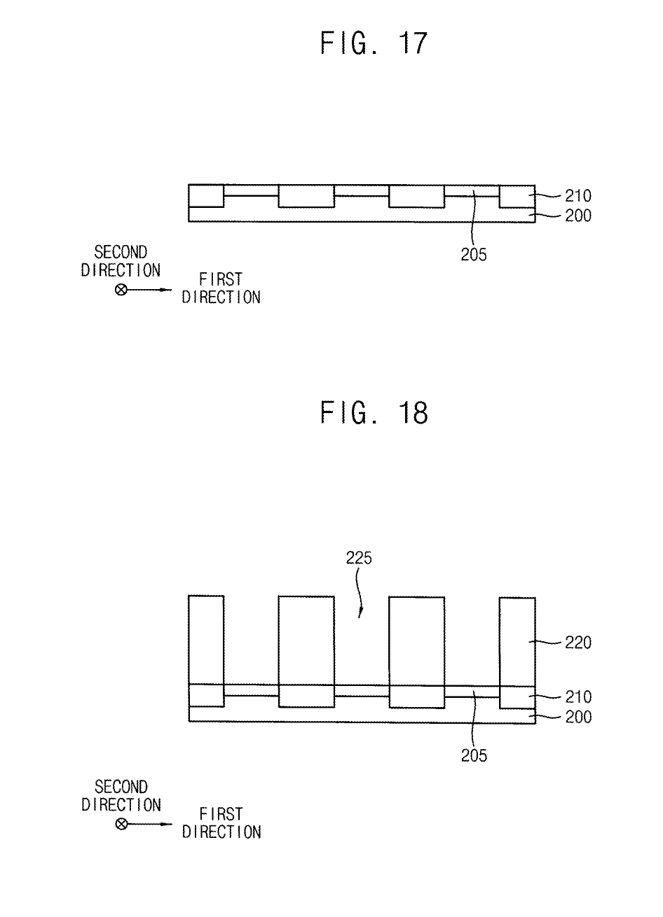

FIGS. 16 to 29 are plan views and cross-sectional views illustrating a method of manufacturing a phase change memory device in accordance with other example embodiments of the present inventive concepts. Particularly, FIGS. 16, 19, 23 and 28 are plan views illustrating the method of manufacturing the phase change memory device, and FIGS. 17, 18, 20, 21, 22, 24, 25, 26, 27 and 29 are cross-sectional views cut along line II-IF of the plan views.

Referring to FIGS. 16 and 17, after an impurity region may be formed by an ion implantation process onto an upper portion of a substrate 200, an isolation layer pattern 210 may be formed at an upper portion of the substrate 200 to divide the substrate 200 into an active region and a field region, and word lines 205 may be formed.

According to example embodiments, the impurity region may be formed by implanting first impurities, e.g., n-type impurities such as phosphorus, arsenic, etc., or p-type impurities such as boron, gallium, etc., into the upper portion of the substrate 200. In an example embodiment, the first impurities may be n-type impurities. Before forming the impurity region, a well region (not illustrated) doped with impurities of a conduction type that is different from the conduction type of the first impurities may be formed in the substrate 200.

In example embodiments, the isolation layer pattern 210 may be formed by a shallow trench isolation (STI) process. That is, after trenches 205 may be formed on the substrate 200, an isolation layer may be formed on the substrate 200 to sufficiently fill the trenches 205, and an upper portion of the isolation layer may be planarized until a top surface of the substrate 200 may be exposed to form the isolation layer pattern 210. According to example embodiments, the isolation layer may be formed using a silicon oxide, e.g., boro-phospho silicate glass (BPSG), phospho-silicate glass (PSG), undoped silicate glass (USG), flowable oxide (FOX), tetra-ethyl ortho-silicate (TEOS), plasma enhanced tetra-ethyl ortho-silicate (PE-TEOS), high density plasma chemical vapor deposition (HDP-CVD) oxide, etc. In example embodiments, the planarization process may be performed by a chemical mechanical polishing (CMP) process and/or an etch back process. In example embodiments, the isolation layer pattern 210 may be formed to extend in a first direction parallel to the top surface of the substrate 200, and a plurality of isolation layer patterns 210 may be formed in a second direction substantially perpendicular to the first direction. Accordingly, the active region of the substrate 200 may also be formed to extend in the first direction, and a plurality of active regions may be formed in the second direction.

In example embodiments, the isolation layer patterns 210 may be formed to have a bottom surface lower than a surface of the impurity region, and thus the impurity region formed at an upper portion of the active region may be divided into a plurality of word lines 205 by the isolation layer patterns 210. In example embodiments, each word line 205 may extend in the first direction, and a plurality of word lines 205 may be formed in the second direction.

Referring to FIG. 18, a first insulating interlayer 220 having a plurality of first contact holes 225 therethrough, which may be arranged in both of the first and second directions at, for example, regular distances, may be formed on the substrate 200 and the isolation layer patterns 210. The first contact holes may also be formed at random intervals. The first contact holes 225 may form a first contact hole array.

The first contact holes 225 may be formed by forming the first insulating interlayer 220 on the substrate 200, and etching the first insulating interlayer 220 anisotropically to expose top surfaces of the word lines 205 of the substrate 200.

The first insulating interlayer 220 may be formed to include an insulating material such as an oxide, a nitride, etc.

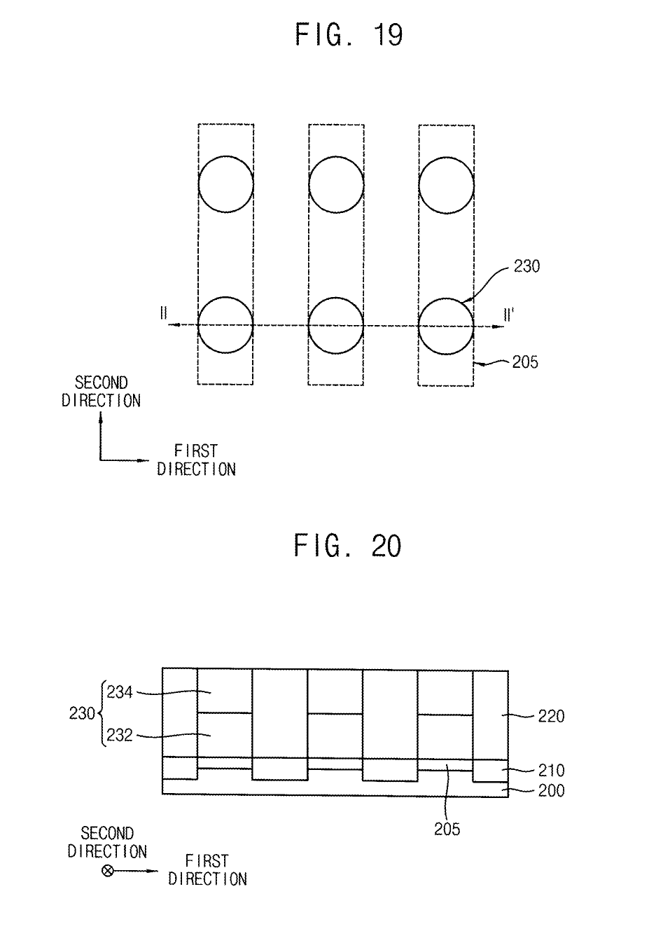

Referring to FIGS. 19 and 20, a diode 230 may be formed to fill each or at least one first contact hole 225.

In example embodiments, a selective epitaxial growth (SEG) process may be performed using the exposed top surfaces of the word lines 205 as a seed layer to form a silicon layer filling the first contact holes 225, and second and third impurities may be implanted into lower and upper portions of the silicon layer, respectively, to form the diode 230. Accordingly, the lower and the upper portions of the silicon layer may be defined as a lower diode layer 232 and an upper diode layer 234, respectively, and the lower diode layer 232 may contact the top surfaces of the word lines 205. Before implanting the second and third impurities thereinto, a planarization process may be further performed on a top surface of the silicon layer, so that a top surface of the diode 230 may have a height substantially the same as that of the first insulating interlayer 220.

In an example embodiment, the second impurities may include n-type impurities, e.g., phosphorous, arsenic, etc., and the third impurities may include p-type impurities, e.g., boron, gallium, etc.

According to example embodiments, the diode 230 may be formed in each or at least one first contact hole 225, and thus a plurality of diodes 230 may be formed to form a diode array.

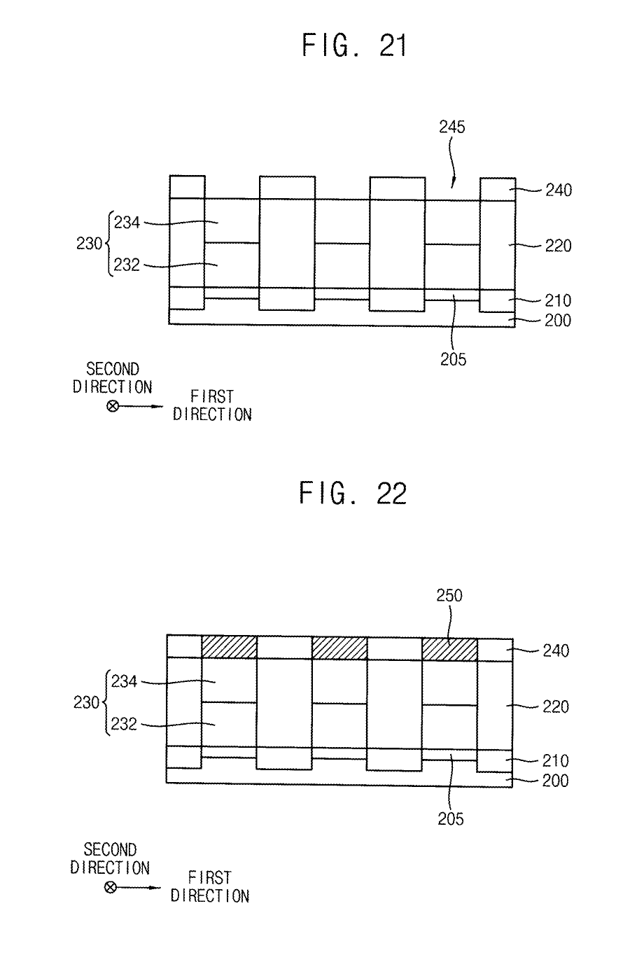

In other example embodiments, a metal layer (not illustrated) may be formed on the diode 230 and the first insulating interlayer 220, and the metal layer and silicon of the diode 230 may react with each other via a heat treatment process to form an ohmic pattern (not illustrated), which may reduce a contact resistance between the diode 230 and a lower electrode 250 (refer to FIG. 21) subsequently formed. In example embodiments, the metal layer may include a metal such as cobalt, nickel, tungsten, etc., and thus the ohmic pattern 240 may include a metal silicide such as cobalt silicide, nickel silicide, tungsten silicide, etc. A portion of the metal layer that has not reacted may be reduced or removed.

Alternatively, the ohmic pattern 240 may be formed by directly implanting metal ions into an upper portion of the diode 230.

Referring to FIG. 21, processes substantially the same as or similar to or the same as the processes illustrated with reference to FIG. 18 may be performed, so that a second insulating interlayer 240 having a plurality of second contact holes 245 therethrough, which may be arranged in the first and second directions at regular distances, may be formed on the first insulating interlayer 220 and the diode 230.

That is, the second contact holes 245 may be formed by forming the second insulating interlayer 240 on the first insulating interlayer 220 and the diode 230 using an insulating material such as an oxide, a nitride, etc., and etching the second insulating interlayer 240 anisotropically to expose top surfaces of the diode 230. The second contact holes 245 may form a second contact hole array.

Referring to FIG. 22, a lower electrode 250 may be formed to fill each second contact hole 245. Thus, a plurality of lower electrodes 250 may be formed both in the first and second directions to form a lower electrode array.

In example embodiments, the lower electrode 250 may be formed by forming a lower electrode layer on the exposed top surfaces of the diode 230, sidewalls of the second contact holes 245 and a top surface of the second insulating interlayer 240, and by planarizing upper portions of the lower electrode layer until a top surface of the second insulating interlayer 240 may be exposed. For example, the lower electrode layer may include a metal or a metal nitride.

In other example embodiments, a contact plug (not illustrated) including a conductive metal may be further formed between the lower electrode 250 and the diode 230.

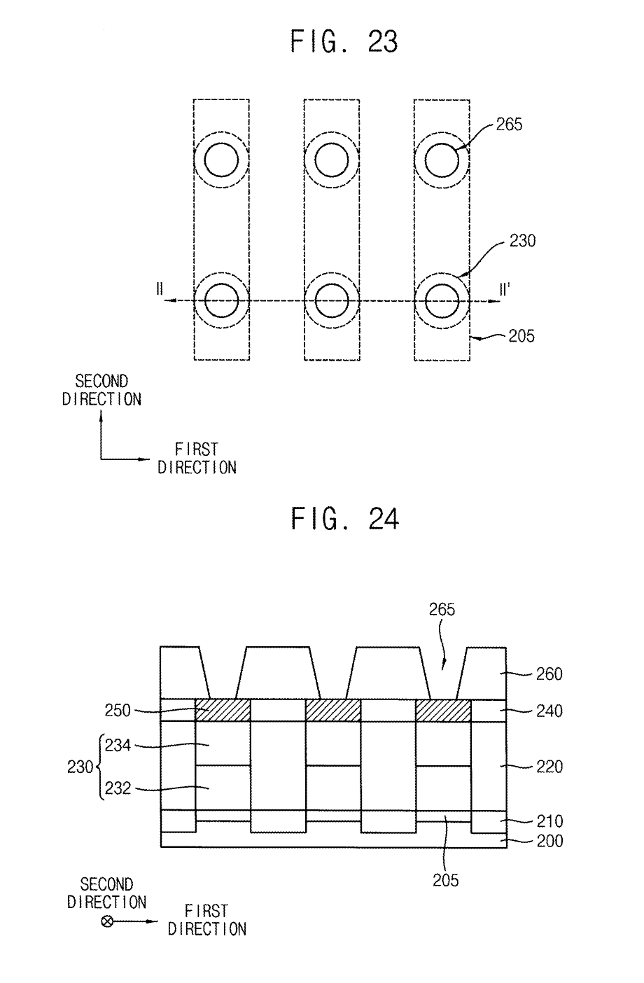

Referring to FIGS. 23 and 24, a third insulating interlayer 260 having a first opening 265 exposing a top surface of the lower electrode 250 may be formed on the second insulating interlayer 240.

In example embodiments, a sidewall of the first opening 265 may be inclined as illustrated in FIG. 24. Further, the first opening 265 may partially expose a top surface of the lower electrode 250. That is, a bottom surface of the first opening 265 may have an area which may be less than the area of a top surface of the lower electrode 250.

Accordingly, as a contact area between a phase change material layer pattern 275 and the lower electrode 250 decreases, the lower electrode 250 may effectively heat the phase change material layer pattern 275 with a relatively low current.

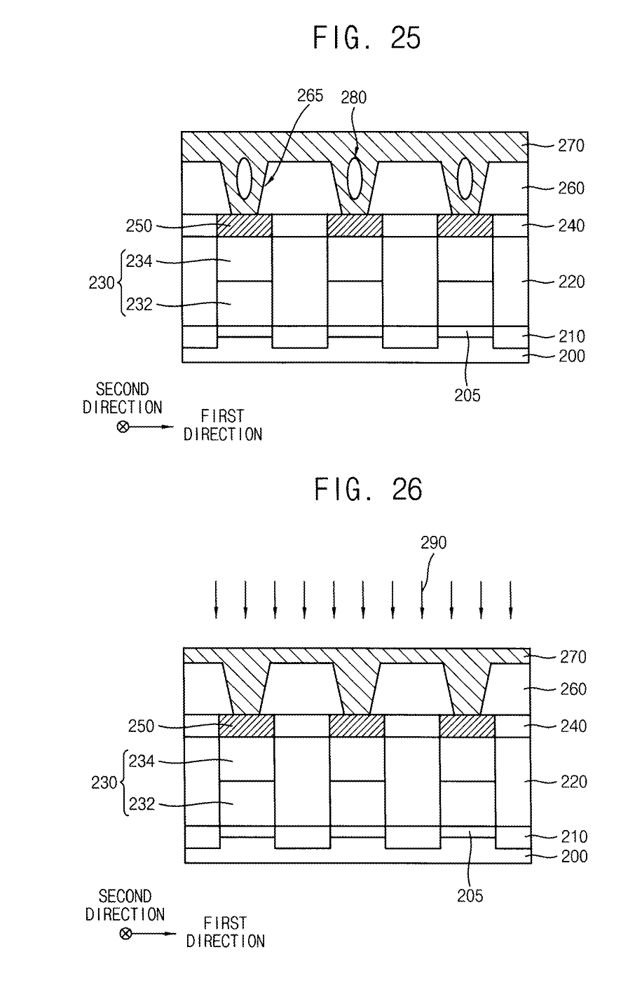

Referring to FIG. 25, the phase change material layer 270 may be formed on the third insulating interlayer 260 to at least partially fill the first opening 265.

The phase change material layer 270 may be formed using a chalcogenide compound described with reference to FIG. 2. In example embodiments, the phase change material layer 270 may be formed via a physical vapor deposition (PVD) process, a CVD process, a low pressure CVD (LPCVD) process, a plasma enhanced CVD (PECVD) process, a high density plasma-CVD (HDP-CVD) process, an ALD process, etc.

As an aspect ratio of the first opening 265 increases, and a width of the first opening 265 decreases, the phase change material layer 270 may at least partially fill the first opening 265. That is, the void 280 may possibly or inevitably appear in the phase change material layer 270.

In example embodiments, the void 280 may be disposed in the phase change material layer 270. That is, the void 280 may be entirely substantially surrounded by the phase change material layer 140.

In other example embodiments, the void may be disposed at an upper portion of the phase change material layer 270. That is, the void may be at least partially surrounded by the phase change materially layer 270, and may be at least partially exposed to an outer space environment.

In other example embodiments, an upper portion and a lower portion of the phase change material layer 270 may have different compositions as described with reference to FIG. 14.

In other example embodiments, a top surface of the phase change material layer 270 may have different surface roughnesses as described with reference to FIG. 9.

Referring to FIG. 26, a laser beam 290 may be irradiated onto the phase change material layer 270, and the material layer 270 may be heated to a temperature above a melting temperature thereof, so that the void 280 may be reduced or removed

The process for irradiating the laser beam 290 may be substantially similar to or the same as the process described with reference to FIG. 3, FIG. 6, FIG. 10, FIGS. 12 and 13 or FIG. 15.

Accordingly, the void 280 in the phase change material layer 270 may be reduced or removed. In other example embodiments, the upper portion of the lower portion of the phase change material layer 270 may become substantially uniform. Alternatively, a surface roughness of the top surface of the phase change material layer 270 may decrease.

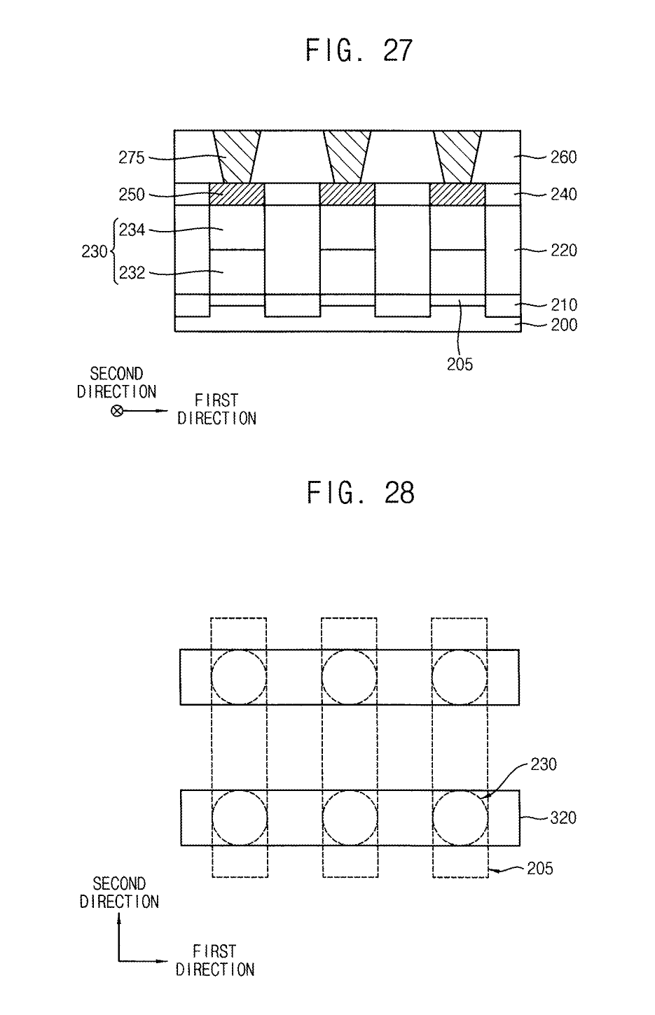

Referring to FIG. 27, the upper portion of the phase change material layer 270 may be planarized to form the phase change material layer pattern 275.

In example embodiments, the upper portion of the phase change material layer 270 may be planarized by a CMP process and/or an etch back process.

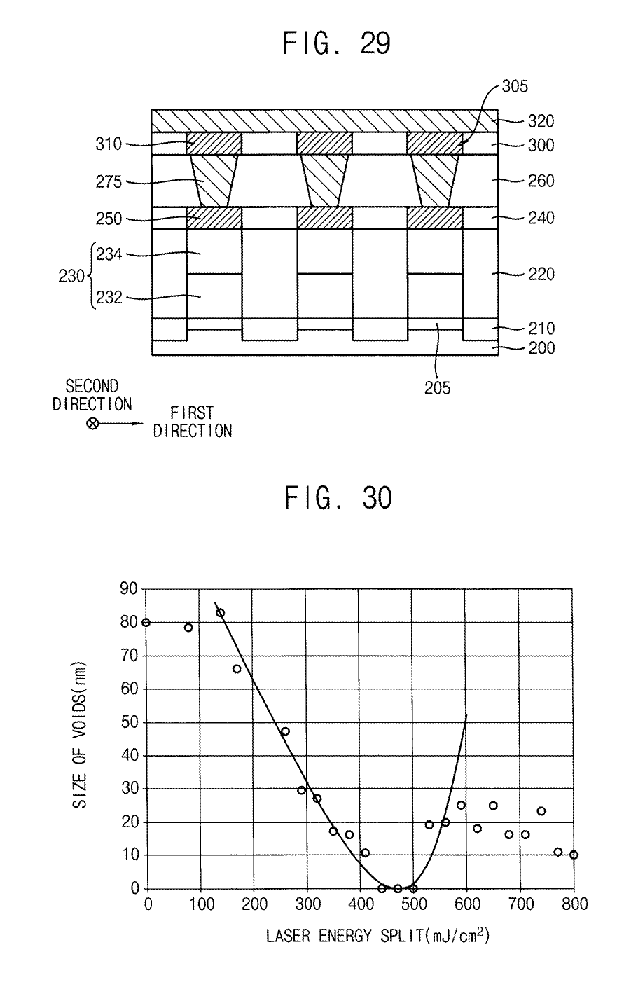

Referring to FIGS. 28 and 29, a fourth insulating interlayer 300 may be formed to include a second opening 305 which exposes a top surface of the phase change material layer pattern 275. An upper electrode 310 and a bit line may be sequentially formed to fill the second opening 305.

According to example embodiments, the upper electrode 310 may be formed by, for example, the following steps. That is, after a second conductive layer may be formed on the exposed top surfaces of the phase change material layer patterns 275 and top surfaces of the fourth insulating interlayer 300 to substantially sufficiently fill the second openings 305, the second conductive layer may be planarized until the top surface of the fourth insulating interlayer 300 may be exposed, and upper portions of the planarized second conductive layer may be reduced or removed by, e.g., a wet etching process to form the upper electrode 310. Accordingly, the upper electrode 310 may be formed to substantially cover the top surface of each phase change material layer pattern 275.

A third conductive layer may be formed on top surfaces of the upper electrodes 310 and the fourth insulating interlayer 300 to sufficiently or substantially fill spaces from which the upper portions of the second conductive layer are reduced or removed, and the third conductive layer may be planarized until the top surface of the fourth insulating interlayer 300 may be exposed to form the bit line 320.

In example embodiments, the plurality of second openings 305 may be formed in the first direction, and thus a plurality of upper electrodes 310 may be also formed in the first direction to form an upper electrode column. As a result, a plurality of bit lines 320 may be also formed in the first direction.

In example embodiments, the fourth insulating interlayer 300 may include an insulating material such as an oxide, a nitride, etc., the second conductive layer may be formed to include, e.g., a metal, a metal nitride, a metal silicide, etc., and the third conductive layer may include a low resistance metal, e.g., copper, aluminum, tungsten, etc.

In an example embodiment, the bit line 320 may have a barrier layer pattern (not illustrated) including, e.g., a metal nitride.

According to example embodiments, the first laser beam 290 generated from the solid state laser medium may be irradiated onto the phase change material layer 270, so that the void 280 may be reduced or effectively removed. Therefore, the phase change material layer pattern 275 may sufficiently or substantially fill the first opening 265 having a relatively large aspect ratio.

FIG. 30 is a graph showing a size of a void in a phase change material layer depending on an energy density of a laser beam.

For example, a lower electrode is formed on a substrate, and an insulation layer is formed on the substrate to cover the lower electrode. The insulation layer is reduced or partially removed to form an opening which may expose the lower electrode. A height of the opening may be about 100 nm, and a width of the opening may be less than about 100 nm.

Then, a phase change material layer is formed by a sputtering process using carbon doped Ge—Sb—Te material. Therefore, a void having a size of about 80 nm is formed in the phase change material layer. The size of the void is defined by a distance between a top surface of the void and a bottom surface of the void.

Then, a laser beam is irradiated onto the phase change material layer for about 600 ns. The energy density of the laser beam changed at each example, and the resulting size of the void is measured, after the laser irradiation.

When the energy density of the laser beam is greater than about 500 mJ/cm², the phase change material layer was vaporized, or was damaged by an ablation. Therefore, a surface roughness increased.

When the energy density of the laser beam is in a range of about 440 mJ/cm² to about 500 mJ/cm², the void in the phase change material layer may be sufficiently reduced or removed.

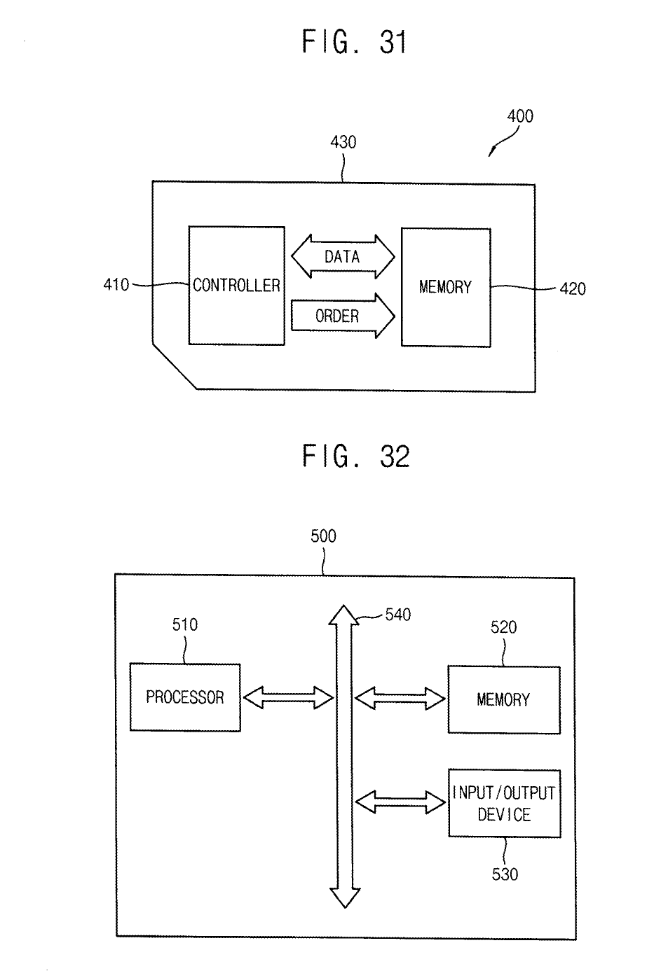

FIG. 31 is a diagram schematically illustrating a memory system 400 according to example embodiments of inventive concepts.

Referring to FIG. 31, a controller 410 and a memory 420 may be disposed to exchange electric signals. For example, the memory 420 and the controller 410 may transfer data with each other according to a command of the controller 410. Accordingly, the memory system 400 may store data in the memory 420 or output data from the memory 420.

The memory 420 may include one of the nonvolatile memory devices that may be manufactured by the method described with reference to FIGS. 1-29. However, a type of memory device used as the memory 420 is not limited thereto, and may be a dynamic random access memory (DRAM), a static random access memory (SRAM), a flash memory, a phase change RAM (PRAM), or the like.

The memory system 400 may be used for different mobile electronic devices, such as a multi media card (MMC) and a secure digital (SD) card.

FIG. 32 is a diagram illustrating a system 500 according to example embodiments of inventive concepts.

Referring to FIG. 31, a processor 510, an input/output device 530, and a memory 520 may communicate with each other by using a bus 540. The processor 510 may execute a program and control the system 500. The input/output device 530 may input or output data of the system 500. The system 500 may be connected to an external device, such as a personal computer or a network, via the input/output device 530 so as to exchange data with the external device.

The memory 520 may store a code or data for operation of the processor 510. The memory 520 may include one of the nonvolatile memory devices that may be manufactured by method described with reference to FIGS. 1-29. However, a type of memory device used as the memory 520 is not limited thereto, and may include a DRAM, SRAM, a flash memory, a PRAM, or the like.

For example, the system 500 may be used in different mobile electronic devices, such as mobile phones, MP3 players, navigation, solid state disks (SSDs), and household appliances.

The present inventive concepts may be applied to various electronic systems including semiconductor chips such as various communication systems and storage systems.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concepts. Accordingly, all such modifications are intended to be included within the scope of the inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of filling an opening, the method comprising:
forming an insulation layer on a substrate, the insulation layer having an opening;
forming a material layer on the insulation layer, the material layer filling the opening and having a void; and
irradiating a first laser beam onto the material layer, thereby removing the void or reducing a size of the void.

2. The method of claim 1, wherein the material layer includes a chalcogenide compound.

3. The method of claim 1, wherein the first laser beam is an yttrium-aluminum-garnet (YAG) laser beam.

4. The method of claim 1, wherein the first laser beam has a wavelength in a range of about 500 nm to about 600 nm.

5. The method of claim 1, wherein an irradiation time of the first laser beam is in a range of about 300 ns to about 1200 ns.

6. The method of claim 1, wherein an energy density of the first laser beam is in a range of about 440 mJ/cm² to about 1000 mJ/cm².

7. The method of claim 6, wherein the energy density of the first laser beam is in a range of about 440 mJ/cm² to about 500 mJ/cm².

8. The method of claim 1, wherein the first laser beam is irradiated under an inert gas atmosphere.

9. The method of claim 1, wherein irradiating the first laser beam includes causing the void to move above a desired height.

10. The method of claim 9, further comprising removing an upper portion of the material layer which surrounds the void, after irradiating the first laser beam.

11. The method of claim 1, wherein irradiating the first laser beam includes reducing a surface roughness of a top surface of the material layer.

12. The method of claim 1, further comprising irradiating a second laser beam onto the material layer, before irradiating the first laser beam.

13. The method of claim 12, wherein irradiating the second laser beam includes forming a capping layer by oxidizing an upper portion of the material layer, and
an energy density of the second laser beam is lower than an energy density of the first laser beam.

14. The method of claim 1, wherein irradiating the first laser beam includes uniformizing compositions of an upper portion and a lower portion of the material layer.

15. A method of manufacturing a phase change memory device, the method comprising:
forming a switching structure on a substrate;
forming a lower electrode electrically connected to the switching structure;
forming an insulation layer having an opening, the opening exposing at least a portion of the lower electrode;
forming a phase change material layer on the insulation layer, the phase change material layer filling the opening and having a void;
irradiating a first laser beam onto the phase change material layer, thereby removing the void or reducing a size of the void;
planarizing an upper portion of the phase change material layer to form a phase change material layer pattern filling the opening; and
forming an upper electrode on the phase change material layer pattern.

16. The method of claim 1, wherein the first laser beam is generated from a solid state laser medium.

17. The method of claim 1, wherein the first laser beam has a wavelength in a range of about 1000 nm to about 1200 nm.

18. The method of claim 1, wherein the first laser beam is irradiated under a reactive gas atmosphere.

19-23. (canceled)
